(19) United States
(12) Patent Application Publication
(10) Pub. No.: US 2016/0181118 A1
(43) Pub. Date: Jun. 23, 2016

(54) PLASMA PROCESSING METHOD

(71) Applicant: HITACHI HIGH-TECHNOLOGIES CORPORATION, Tokyo (JP)

(72) Inventors: Yutaka KUDOU, Tokyo (JP); Tetsuo ONO, Tokyo (JP)

(73) Assignee: HITACHI HIGH-TECHNOLOGIES CORPORATION

(21) Appl. No.: 14/851,691

(22) Filed: Sep. 11, 2015

(30) Foreign Application Priority Data
Dec. 19, 2014 (JP) 2014-256787

(51) Int. Cl. H01L 21/311; H01L 21/02

(52) U.S. Cl. CPC H01L 21/31116; H01L 21/02164; H01L 21/0217; H01L 21/02123

(57) ABSTRACT

A plasma processing method capable of controlling an etching rate of a SiN film and obtaining high selectivity to a SiO₂ film and Si at the same time performs etch-back of a SiN film as a processing object of a film structure including a SiO₂ film and the SiN film or a Si film and the SiN film on a surface of a substrate placed in a processing chamber by using inductively couple plasma formed in the processing chamber by supplying process gas including CHF₃ or CF₄ and O₂ gas into the processing chamber inside a vacuum vessel and supplying RF power of 7-50 MHz to an induction coil surrounding an outer circumference of the processing chamber.

### BACKGROUND OF THE INVENTION

The present invention relates to a plasma processing method for processing a substrate-like sample such as a semiconductor wafer placed in a processing chamber inside a vacuum vessel by using plasma formed in the processing chamber, and in particular, to a plasma processing method for etching a film placed in advance on a sample by forming plasma by inductive coupling in the processing chamber.

Current semiconductor devices have a complicated three-dimensional structure or are made using a technique for new material. In order to cope with construction of these devices, various process techniques are proposed and evaluated. On the other hand, in the progress of fine processing of semiconductor devices, regarding request items in an etching technique, etching rate controllability, high uniformity, and high selectivity are very important items.

In particular, a processing technique around a gate in device construction has been refined and complicated as described above, but especially, there has been an increasing request for high selectivity etching of a SiN film to a SiO₂ film and Si including a poly-Si film.

Regarding the high selectivity etching of the SiN film to the SiO₂ film, various techniques are proposed. As examples of such conventional techniques, JP-A-2010-98101 and the like are known

For example, the JP-A-2010-98101 describes a method for removing an inter-layer insulating film by fluorocarbon gas and then removing a gate oxide film and a SiN film on a side sidewall by using oxidized gas. In addition, JP-A-H06-181190 discloses a method for performing high selective SiN etching to the SiO₂ film by using mixed gas of NF₃ and Cl.

In addition, JP-A-2001-127038 discloses a technique that, in forming a side sidewall of a gate electrode, selectively removes a SiN film by a first step using halogen hydrogen gas, and then removes a gate oxide film by using mixed gas of fluorocarbon gas/He. Furthermore, JP-A-H07-235525 discloses a technique for removing a SiN film by using a halogen element other than element fluorine and thereby performing selective etching to a SiO₂ film.

Furthermore, JP-A-2013-503482 describes a technique that makes reactive oxygen flow while producing a precursor containing fluorine and hydrogen by using remote plasma, and etches a layer containing silicon carbon. Then, the technique sublimes a solid byproduct by making temperature higher than sublimation temperature of the solid byproduct on a surface.

### SUMMARY OF THE INVENTION

The above-described conventional techniques have caused problems because they do not fully take the following points into consideration.

More specifically, in processing to deal with a film using new material that has a high possibility of being used in semiconductor devices hereafter or in the future, and processing to form a complicated three-dimensional structure, generally, a SiO₂ film is often used as an under-layer film of a SiN film, and such a case has been handled by securing selectivity of the SiN film to the SiO₂ film up to now. However, etching processing to achieve the three-dimensional structure may expose films such as Al₂O₃ and poly-Si in addition to SiO₂, which is an under-layer film of the SiN film, when etching and removing the SiN film as an object film.

In addition, the conventional techniques first conduct etching of the SiN film under a condition of achieving high selectivity until the SiO₂ film is exposed, then conduct etching of the SiO₂ film under a condition of being able to obtain selectivity to an undermost-layer film until the undermost-layer film such as poly-Si is exposed. Such a processing step requires etching of a plurality of film layers of a film structure in which a plurality of film layers including a mask are overlapped, therefore the number of processing sub-steps increases, and time to process a sample per sheet increases; as a result, it has caused a problem of impairing the number of sheets per unit time (so-called throughput) as a whole when samples with specification having material and structure dimensions being the same or similar in the degree regarded as the same on a lump of a plurality of sheets of samples are processed under the same condition or a similar condition in the degree regarded as the same. On the other hand, trying to improve throughput by making an etching rate of the SiN film higher causes problems, such as being difficult to obtain desired etching characteristics, for example, selectivity or uniformity in an in-plane direction of a shape obtained after processing, and reducing its repeatability.

Therefore, the conventional techniques require processing that can achieve both height of the selectivity of the SiN film to the SiO₂ film and to the poly-Si film, and desired etching speed depending on a film and film thickness to be processed. If such processing is obtained, undue increase in the number of sub-steps and loss in processing throughput due to the increase will be prevented.

An object of the present invention is to provide a processing method that enables control of an etching rate of the SiN film and obtaining high selectivity to the SiO₂ film and Si at the same time in selective etching of the SiN film to the SiO₂ film and to Si.

In addition, another objective is to provide a process processing method that also exhibits high selectivity of the SiN film to an under-layer film of the SiO₂ film and poly-Si film and is able to control an etching rate.

The above-described objectives are achieved by a plasma processing method that performs etch-back of a SiN film as a processing object of a film structure including a SiO₂ film and the SiN film or a Si film and the SiN film on a surface of a substrate placed in a processing chamber by using inductively coupled plasma formed into the processing chamber by supplying process gas including CHF₃ or CF₄ and O₂ gas in the processing chamber inside a vacuum vessel, and supplying RF power of 7-50 MHz to an induction coil surrounding an outer circumference of the processing chamber.

The present invention can shorten time for etching processing and thereby improves throughput.

Other objects, features and advantages of the invention will become apparent from the following description of the embodiments of the invention taken in conjunction with the accompanying drawings.

### BRIEF DESCRIPTION OF THE DRAWINGS

FIG. 1 is a longitudinal sectional view schematically showing outline of a configuration of a plasma processing apparatus according to an example of the present invention;

FIG. 2 is a graph showing correlations between processing rates of a SiO₂ film, a SiN film and a poly film and a flow rate of CHF₃ when a wafer was processed under conditions in FIG. 4 in the plasma processing apparatus according to the example shown in FIG. 1;

FIG. 3 is a graph showing correlations between selectivity of the SiO₂ film, SiN film and poly film and the flow rate of CHF₃ when a wafer was processed under the conditions in FIG. 4 in the plasma processing apparatus according to the example shown in FIG. 1;

FIG. 4 is a table describing the conditions of processing in studies in FIG. 2 and FIG. 3;

FIG. 5 is a graph showing correlations between in-plane uniformity and the flow rate of CHF₃ obtained by studying a result of processing under the conditions shown in FIG. 4 in the plasma processing apparatus according to the example shown in FIG. 1;

FIG. 6 is a graph showing correlations between processing speed (rates) of the SiO₂ film, SiN film and poly film and a flow rate of CF₄ obtained by studying a result of processing under the conditions shown in FIG. 4 in the plasma processing apparatus according to the example shown in FIG. 1;

FIG. 7 is a graph showing correlations between selectivity and the flow rate of CF₄ obtained by studying a result of processing under the conditions shown in FIG. 4 in the plasma processing apparatus according to the example shown in FIG. 1;

FIG. 8 is a graph showing correlations between in-plane uniformity and the flow rate of CF₄ obtained by studying a result of processing under the conditions shown in FIG. 4 in the plasma processing apparatus according to the example shown in FIG. 1;

FIG. 9 is a graph showing correlations between processing rates of the SiO₂ film, the SiN film and a poly-Si film and concentration of O₂ in the plasma processing apparatus according to the example shown in FIG. 1,

FIG. 10 is a graph showing correlations between selectivity of processing of the SiO₂ film, SiN film and poly-Si film and the concentration of O₂ in the plasma processing apparatus according to the example shown in FIG. 1;

FIG. 11 is a graph showing correlations between rates and processing pressure in processing a plurality of types of films in the plasma processing apparatus according to the example shown in FIG. 1;

FIG. 12 is a graph showing correlations between selectivity and pressure in processing the plurality of types of films in the plasma processing apparatus according to the example shown in FIG. 1,

FIG. 13 is a table describing a result of processing a wafer when high-frequency power of multiple frequencies was supplied to an induction coil in the plasma processing apparatus according to the example shown in FIG. 1;

FIG. 14 is a table describing conditions of processing a wafer performed in the plasma processing apparatus according to the example shown in FIG. 1;

FIG. 15 is a graph showing comparison of light emission intensity from plasma between when a wafer was processed using mixed gas of O₂, CF₄ and CHF₃ in the plasma processing apparatus according to the example shown in FIG. 1 and when a processing apparatus using ECR plasma was used;

FIG. 16 is a graph showing light emission intensity of O₂⁺ and integrated light emission intensity of spectra of wavelengths from 1 nm to 900 nm when a wafer was processed in the plasma processing apparatus according to the example shown in FIG. 1;

FIG. 17 is a graph showing relation between an aspect ratio and an etching rate and its uniformity when a wafer was processed in the plasma processing apparatus according to the example shown in FIG. 1;

FIG. 18 is a longitudinal sectional view schematically showing a processed shape as a result of processing a wafer by using the conditions shown in FIG. 14 in the plasma processing apparatus according to the example shown in FIG. 1;

FIG. 19 is a graph showing relation between a duty ratio of power and selectivity when a wafer was processed by applying pulse modulation to output of a high-frequency power supply and supplying it to the induction coil;

FIG. 20 is a longitudinal sectional view schematically showing outline of a configuration of a plasma processing apparatus according to a variant example of the example shown in FIG. 1;

FIG. 21 is a graph showing change of output from two high-frequency power supplies over time in the variant example shown in FIG. 20;

FIG. 22 is a graph showing change of output from the two high-frequency power supplies over time in the variant example shown in FIG. 20;

FIG. 23 is a graph showing change of output from the two high-frequency power supplies over time in the variant example shown in FIG. 20; and

FIG. 24 is a longitudinal sectional view schematically showing outline of a configuration of a plasma processing apparatus according to a further variant example of the example shown in FIG. 1.

### DESCRIPTION OF THE EMBODIMENTS

Embodiments of the present invention will be explained using the drawings.

### EXAMPLE 1

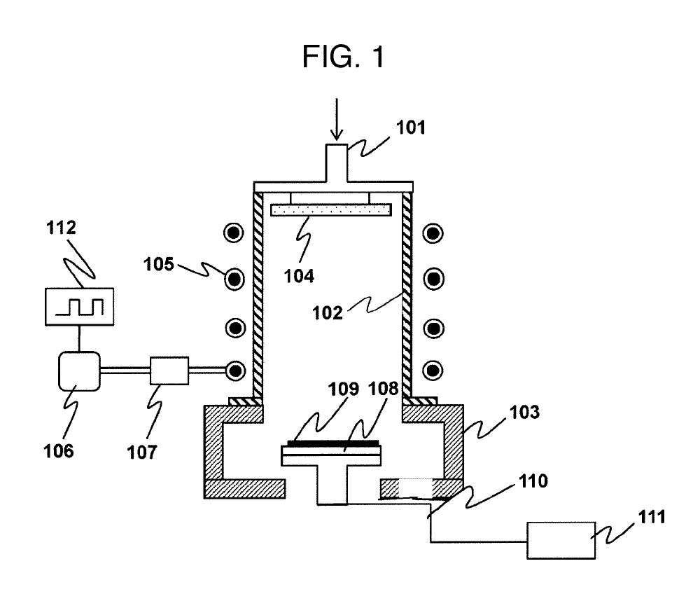

An example of the present invention will be explained below using FIGS. 1 to 23.

FIG. 1 is a longitudinal sectional view schematically showing outline of a configuration of a plasma processing apparatus according to an example of the present invention. The plasma apparatus of the example is a so-called helical antenna-type processing apparatus that uses inductively coupled plasma and that forms the plasma formed in a processing chamber placed inside a vacuum vessel by exciting process gas supplied into the processing chamber by using an inductive magnetic field that is formed in the processing chamber by supplying high-frequency power of a prescribed frequency to an antenna arranged outside the vacuum vessel in a spiral manner surrounding the processing chamber.

The vacuum vessel of the example comprises: a gas supply plate 101 including a top board made of dielectric material for functioning as a lid: a quartz chamber 102 that is made of quartz and cylindrical, and on an upper end of that an outer peripheral rim of the gas supply plate 101 is placed, wherein a seal member is wedged between a bottom surface of the gas supply plate 101 and a top surface of the quartz chamber 102 to seal the inside from the outside in an airtight manner; and a chamber 103 that is made of aluminum, and between it and the quartz chamber 102 wedged is a seal member that seals the inside from the outside in an air tight manner by its top surface contacting with the bottom surface of the lower end of the quartz chamber 102. The gas supply plate 101 forming an upper part of the vacuum vessel is a plate-shaped member forming a ceiling or the inside processing chamber and one or multiple gas supply ports are arranged. Furthermore, under the gas supply ports, a quartz battle plate 104 for distribution is placed in order to efficiently distribute gas flowing into the center of the cylindrical processing chamber to an outer circumference.

The quartz chamber 102 is composed of cylindrical quartz placed so as to surround the outer circumference of the processing chamber, on the outer circumference of an outer wall of it, placed with a gap is an induction coil 105 wound in multiple steps such that distance between the steps in a vertical direction is equal. The induction coil 105 is, at its end, electrically connected with an unshown high-frequency power supply for supplying high-frequency power 106 of a prescribed frequency (27.12 MHz in the example), and generates an induction magnetic field in the processing chamber inside the quartz chamber 102 by the high-frequency power 106 supplied to the induction coil 105 by the high-frequency power supply.

Between the high-frequency power supply 106 and the induction coil 105, an auto matcher 107 is placed that automatically adjusts impedance at an equivalent circuit so that reflection of power from plasma which is a load at the equivalent circuit including plasma formed in the processing chamber will be at a desired value or below in order to widen a plasma margin. In the evaluation, the high-frequency power 106 of 27.12 MHz is applied to the induction coil 105, but high-frequency power of another frequency, for example, 13.56 MHz can be also applied. In addition, a pulse modulator 112 is electrically connected with the high-frequency power supply 106, and a value of output of the high-frequency power supply 106, for example amplitude, is increased or decreased periodically according to increase or decrease of a value of a pulse signal output at a prescribed cycle from the pulse modulator 112.

In addition, at a lower part of the processing chamber placed inside the quartz chamber 102, a wafer mounting stage 108 having a cylindrical or discoid shape is placed such that its center axis is aligned with a center axis of the cylindrical part of the processing chamber or quartz chamber 102. In addition, the quartz chamber 102 is made such that height of the upper end surface of its cylindrical part is height so as to make plasma distribution over a wafer 109 mounted on the wafer mounting stage 108 uniform.

The process gas introduced from the gas supply ports and distributed to the outer circumference side by the quartz baffle plate 104 at the upper part of the processing chamber inside the quartz chamber 102 descends along a cylindrical inner wall of the quartz chamber 102 toward the downward wafer mounting stage 108 or the wafer 109, a sample mounted on upward of a top surface of the wafer mounting stage 108. Additionally, in the example, gas flow is formed along the inner wall of the quartz chamber 102, and thereby process gas is supplied to a point or its vicinity of an inner wall surface where the induction coil 105 is wound by multiple steps, and in the vicinity the intensity of an induction magnetic field formed by the induction coil 105 is the strongest.

The process gas is excited by the induction magnetic field to form plasma, and active particles such as radicals excited inside the plasma reach atop surface of the wafer 109, cause a chemical action with a processing object film of the surface, and process the film (ashing in the example). In addition, byproduct particles produced at the time of ashing and unconverted process gas are exhausted from an exhaust port 110 to the outside of the processing chamber by operation of an unshown vacuum pump which is placed downward and communicated with the exhaust port 110, an opening of a through-hole placed at a bottom surface of the aluminum chamber 103.

In the example, the wafer mounting stage 108 is made of aluminum, and on its top surface is placed a mounting surface, over which the wafer 109 is mounted with a gap. The mounting surface is provided with a groove to let heat transmission gas go from the front surface of the wafer mounting stage 108 in order to prevent the wafer 109 from hovering by the heat transmission gas supplied between a rear surface of the wafer 109 and the mounting surface to prompt thermal transmission. This is to prevent displacement of the wafer 109 due to hovering of the wafer. Because the wafer mounting stage 108 can prevent displacement of the wafer 109, a pin to prevent displacement and a mechanism to drop the wafer are not provided. Thus, generation of contaminating matters due to edge contact can be prevented because contact due to displacement of the wafer 109 can be reduced.

In addition, in the example, in order to enable etching (ashing) processing that achieves both processing speed (rate) and high selectivity by controlling the speed, temperature of the wafer 109 is maintained at 20-40° C. In order to achieve this, inside the wafer mounting stage 108, there is placed a refrigerant flow channel (not shown) capable of adjusting temperature of the wafer mounting stage 108 by letting refrigerant adjusted at prescribed temperature flow through therein and exchange heat. The refrigerant flow channel is coupled with a circulator 111, a temperature control mechanism, by an external pipe. Between the wafer mounting stage 108 and the circulator 111, the refrigerant whose temperature is adjusted by the circulator 111 circulates.

Next, a processing rate and selectivity in processing using the plasma processing apparatus of the example will be explained.

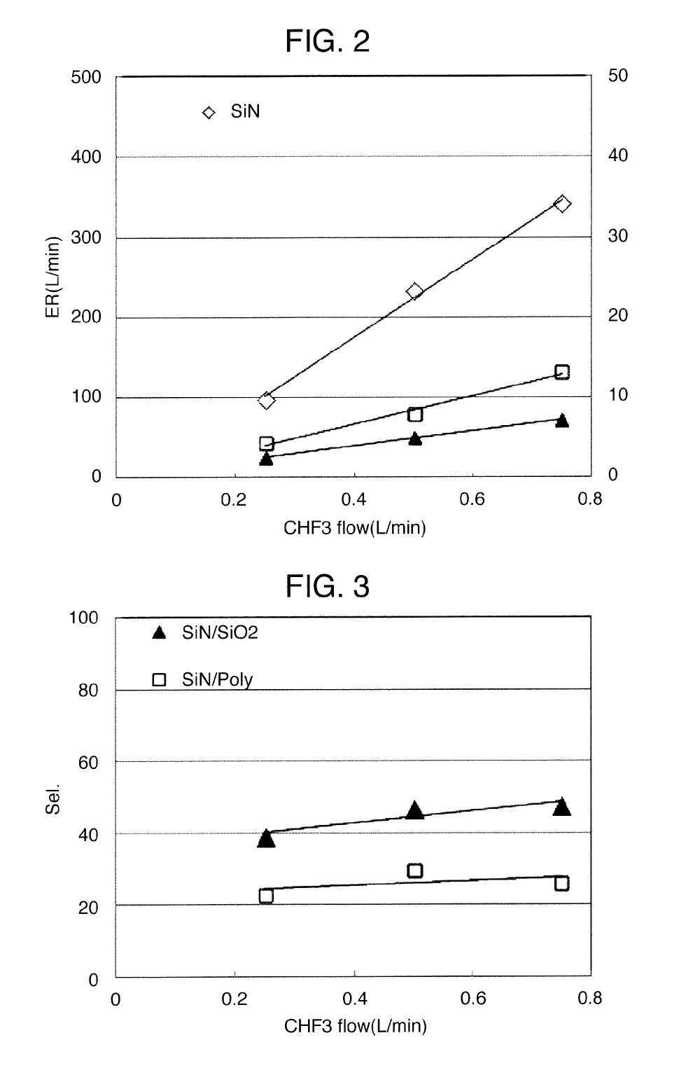

The present inventors studied correlations between processing characteristics such as speed and a flow rate of process gas in the case where processing to remove an object film was performed by applying etching or ashing processing to a film structure of a plurality of types of film layers being overlapped placed on the front surface of the wafer 109 as a sample under particular conditions by using the plasma processing apparatus shown in FIG. 1. Results of this will be explained using FIGS. 2 to 5. As process gas at this time, mixed gas of O₂, CF₄, and CHF₃ was used, and the above parameters were detected about a film structure including a SiO₂ film, a SiN film and a poly film as processing object films.

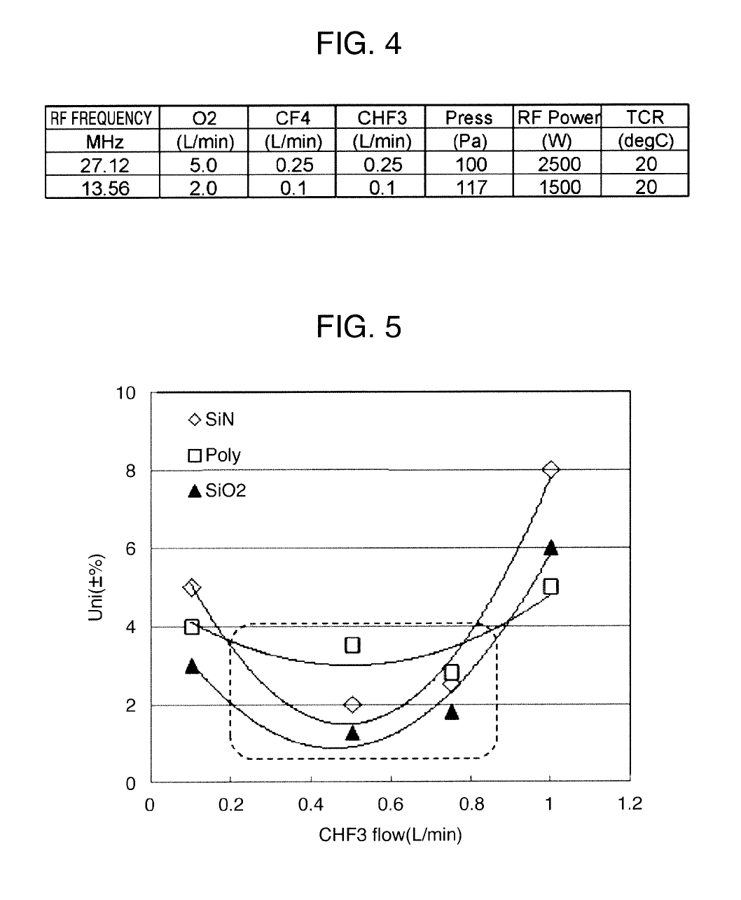

FIG. 2 shows correlations between processing rates of the SiO₂ film, SiN film and poly film and the flow rate of CHF₃ obtained by conducting the above study in the plasma processing apparatus of the example shown in FIG. 1, and FIG. 3 shows correlations between selectivity and the flow rate of CHF₃ obtained by conducting the above study in the apparatus. In addition, FIG. 4 shows processing conditions used for this study.

As shown in FIGS. 2, 3, it is recognized that increase in the flow rate of CHF₃ speeds up the etching rates of the SiO₂ film, SiN film and poly film, and especially the etching rate of the SiN film notably increases. This reaction will be explained using bonding energy.

Bonding involved in this reaction model is considered to be Si—O, Si—N, Si—F and H—F, and their respective bonding energies are as follows:

O—F: 26(Kcal/mol)≦Si—N: 105<Si—F: 132<H—F: 153<Si—O: 195

The SiN film reacts with F radicals of CF₄ and CHF₃ decomposed by plasma to form Si—F bonding. Next, F radicals of Si—F (132 Kcal/mol) and H radicals of decomposed CHF₃ react to form H—F (153 Kcal/mol) bonding. On the other hand, regarding SiO₂, Si—O bonding is high at 195 (Kcal/mol) compared with Si—F and Si—N and hardly decomposes. On top of that, in plasma by a gas ratio in the invention, O radicals are dominant. Therefore, it is considered that compared with the reaction of the SiN film, the reaction is limited.

It is considered from this that increase in the flow rate of CHF₃ notably speeds up only the etching rate of the SiN film compared with the SiO₂ film and poly-Si film. By using the process conditions, varying the flow rate of CHF₃ enables selective etching of only the SiN film to the SiO₂ film and poly-Si film, and also enables controlling the etching rate of the SiN film in a range of 100-350 (nm/min).

According to the result of the selectivity in FIG. 3, together with increase in the flow rate of CHF₃, the selectivity of both SiN/SiO₂ and SiN/poly-Si slightly increases. It is recognized that the selectivity can be adjusted in the ranges of about 40-50 for the selectivity of SiN/SiO₂ and about 20-30 for the selectivity of SiN/poly-Si.

FIG. 5 shows correlations between in-plane uniformity and the flow rate of CHF₃ obtained by studying a result of processing under conditions shown in FIG. 4. As can be seen in the figure, the in-plane uniformity varies according to the flow rate of CHF₃. Assuming that a usable range of the in-plane uniformity that can control performance of a manufactured semiconductor device within a permissible range is at or within ±4%, it has been recognized that regarding the flow rate of CHF₃, the flow rate in a range of 0.2-0.8 L/min can achieve the uniformity.

Next, correlations between processing characteristics and a flow rate of process gas when CF₄ was used as the process gas are explained using FIGS. 6 to 8. First, FIG. 6 shows correlations between processing speed (rates) of the SiO₂ film, SiN film and poly film and a flow rate of CF₄.

As shown in the figure, together with increase in the flow rate of CF₄, the rate of the SiN film decreases but the rates of the SiO₂ film and poly-Si film slightly increase. This is considered that even if the flow rate of CF₄ increases, generation reaction of H-F bonding does not proceed unlike the case of CHF₃, and the etching rate of SiN decreases due to increase in C—F radicals.

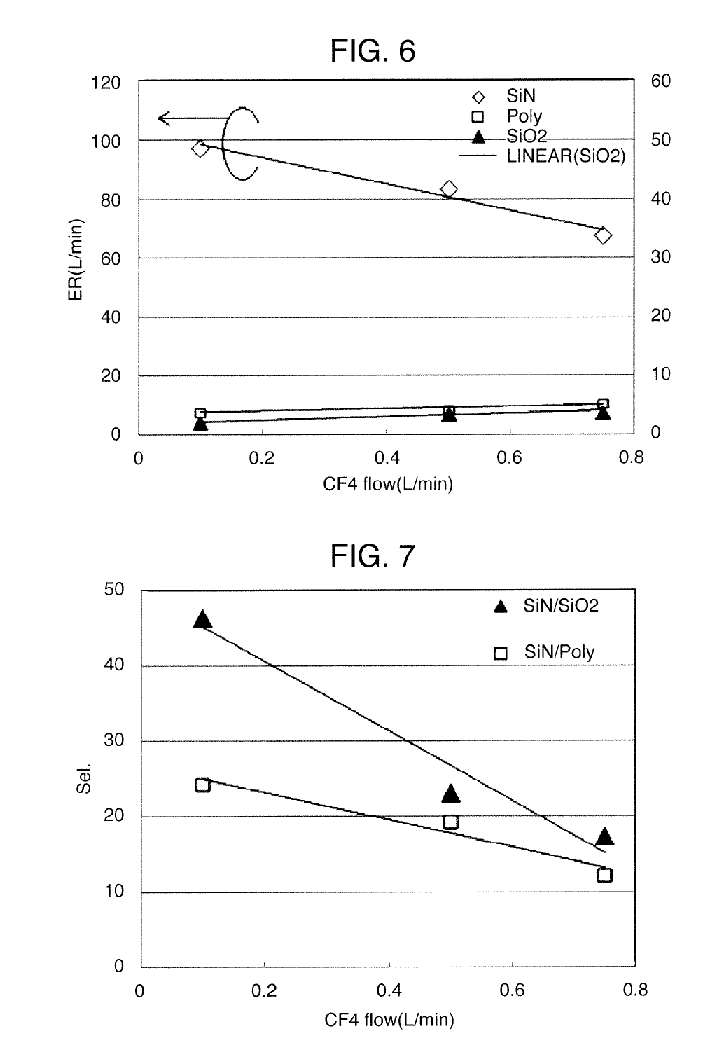

FIG. 7 shows correlations between selectivity and the flow rate of CF₄ in the processing using CF₄. As can be seen in the figure., together with increase in the flow rate of CF₄, the selectivity of both between SiN/SiO₂ and between SiN/poly-Si decreases, and the selectivity between SiN/SiO₂ is about 15-50, and the selectivity between SiN/poly-Si is about 10-25.

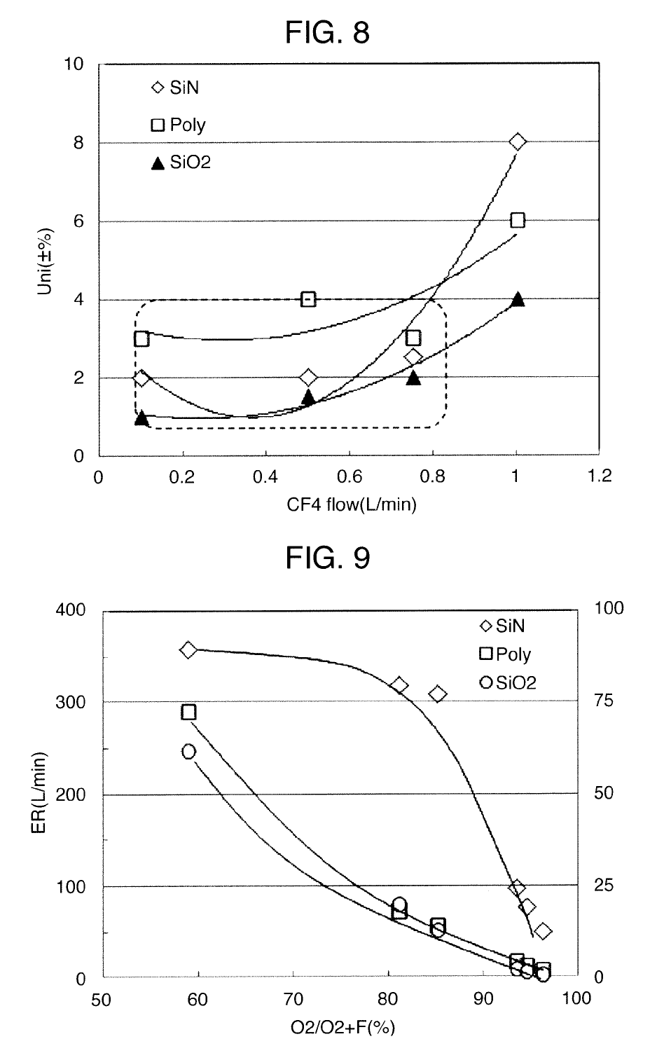

FIG. 8 shows correlations between in-plane uniformity and the flow rate of CF₄ at the processing. In the figure, together with increase in the flow rate of CF₄, the in-plane uniformity of all the film types tends to become worse. Applying a similar criterion to the study in FIG. 5, a range of the flow rate to achieve variation in performance within the permissible range in an actual semiconductor device is 0.1-0.8 L/min.

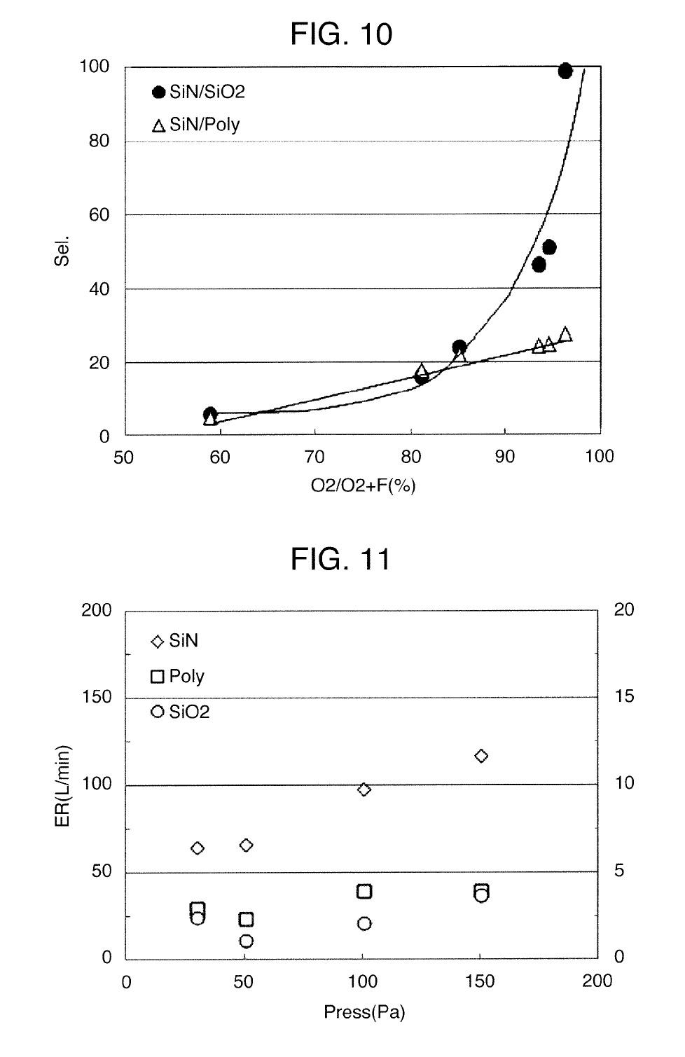

Next, FIG. 9 shows correlations between processing rates of the SiO₂ film, SiN film and poly-Si film and concentration of O₂ (O₂/O₂⁺ fluorine-containing gas (%)), and FIG. 10 shows correlations between selectivity of processing and the concentration of O₂.

As shown in these figures, the etching rate of the SiN film slows as the concentration of O₂ increases, and when the concentration is 80% or more, the etching rate drops from 300 (nm/min) to 100 (nm/min) or below. In addition, the etching rates of SiO₂ and poly-Si also decrease as the concentration of O₂ increases and in the range of the O₂ concentration being 80% or more, both etching rates drop to 10 (nm/min) or below.

It is considered from this that a phenomenon of drop in the etching rates due to increase in the O₂ concentration is caused by a fact that when a ratio of the flow rate of O₂ to the flow rates of CF₄ and CHF₃ is high, byproducts of Si—F (132 Kcal/mol) and Si—O (195 Kcal/mol) are easily generated, and as the bonding is hard to decompose, Si—F bonding and Si—O bonding become dominant, and when the O₂ concentration is high concentration of 80% or more, reaction of Si with O or F is saturated, and reaction is limited.

As shown in FIG. 10, regarding selectivity, the SiN/SiO₂ selectivity steeply rises at the O₂ concentration of 80% or more, and high selectivity of about 100 is obtained. Regarding SiN/poly-Si, selectivity of about 20-30 is obtained at the O₂ concentration of 80% or more.

This study result leads to understanding that using a range of the O₂ concentration being 80% or more as a processing condition enables processing, for example, in a processing time of about 20 s if film thickness of SiN to be removed is about 100 nm in a processing step of removing SiN, and if film thickness of SiN to be removed is about 10 nm, using 80% or more as a processing condition enables processing in a processing time of about 10-20 s. Additionally, in the case of a processing time of 30 s or shorter, there usually is a problem of repeatability of a rate at a time of continuous processing, but it is considered that SiO₂ and poly-Si are not etched or, if any, sufficiently small, because sufficient selectivity is obtained in this region even if they are over-etched.

Using the above condition enables SiN etching removal that achieves high speed and high selectivity in a film thickness range of 10-100 nm.

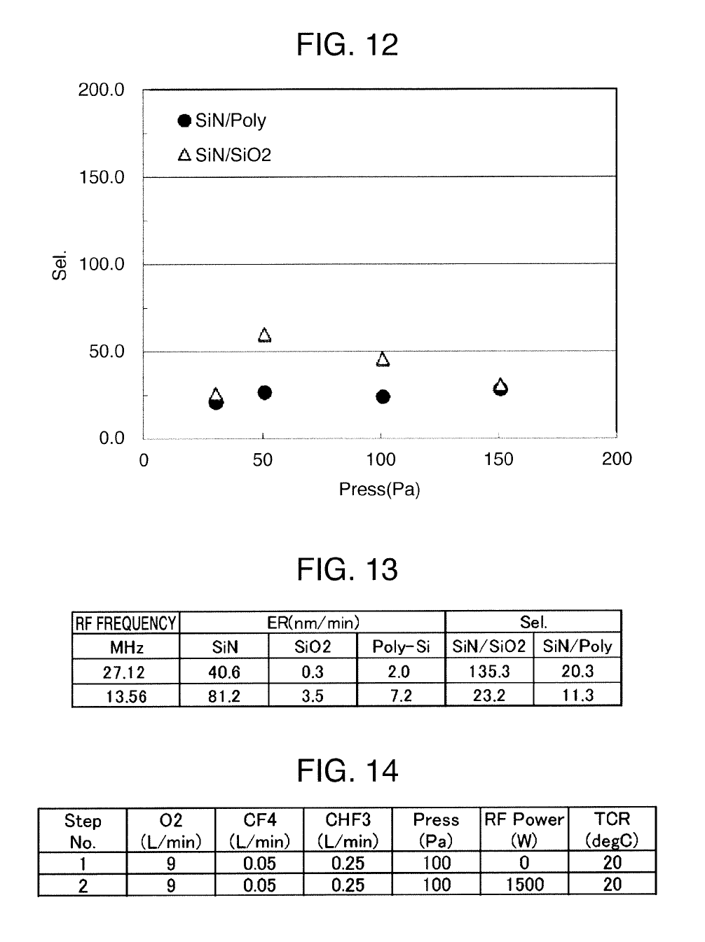

FIG. 11 shows correlations between rates of processing the plurality of types of films and processing pressure, and FIG. 12 shows correlations between selectivity and pressure in the processing.

As shown in FIG. 11, the processing rate of SiN increases as the pressure increases In addition, the rates of poly-Si and SiO₂ are low of 5 nm/min or less. On the other hand, as shown in FIG. 12, regarding the selectivity, selectivity of 25 or more is obtained at 30 Pa or more for both SiN/SiO₂ and SiN/poly. Additionally, it is desirable to use pressure of 50 Pa or more because 30 Pa is a lower limit of exhaust capability of the apparatus.

In this study, the reason to make O₂ concentration higher than fluorine-containing gas concentration is to make O₂ gas function as carrier gas. If the amount of process gas supplied to the processing chamber inside the quartz chamber 102 is small, radicals remain a shorter time around an outer circumference part of the wafer 109 inside plasma, and an impact by flow of gas exhausted from the processing chamber becomes notable in a space at an outer circumference side of the wafer mounting stage 108.

As a result, the number of particles in plasma at the outer circumference rim of the wafer 109 decreases, and reaction of processing decreases. This means that reaction of processing makes progress more at a central part of the wafer 109, and distribution of the processing rate in an in-plane direction of the wafer 109 (in the case of processing using the wafer 109 in a circular form or similar form to that, the direction of a radius or diameter from its center) tends to be convex distribution, and uniformity in the in-plane direction of processing becomes worse.

Increasing O₂ concentration supplied to the processing chamber is a parameter that makes it easy to adjust such a rate to a desired rate and obtains high selectivity, and also can prevent non-uniformity of the processing result in the in-plane direction of the wafer 109.

Next, relation between uniformity of the SiN etching rate and device application will be explained.

First, in the example, two steps of processing were continuously performed under processing conditions shown in FIG. 14. In the conditions, the SiN etching rate is 40 nm/min and the in-plane uniformity is ±2.5%. For example, assuming that etching processing of a SiN film with a film thickness of 20 nm is executed, in the case where etching processing of 20 nm is executed under conditions of a table in FIG. 14, even if processing time is made 30 s, the uniformity does not change and remains at ±2.5%, and variation is 0.5 nm. If the in-plane uniformity becomes ±5%, variation becomes 1 nm, device performance may vary within the plane of the wafer. Therefore, the present invention has adopted an etching condition that the in-plane uniformity of the etching rate is ±4% or less, i.e. variation within the plane of the wafer is 0.8 nm or less as a criterion capable of device application.

Regarding evaluation of the present invention, a shown evaluation result is a result when high frequency of 27.12 MHz was applied to the induction coil 105, but evaluation was also conducted by applying high frequency power of 13.56 MHz to the induction coil 105. The result is shown in FIG. 13. An apparatus used in applying the high frequency of 13.56 MHz this time is different from the apparatus used in the present invention, and is an apparatus different in the number of turns of the helical coil, exhaust capability and specification of MK; therefore etching rate evaluation was conducted by matching a ratio of the flow rate of a process gas condition to the conditions of the present invention.

As a result, the etch rates of the SiN film, SiO₂ film and poly-Si film are 81.0, 3.5, 7.2 (nm/min), the selectivity of SiN/poly is 11.3, the selectivity of SiN/SiO₂ is 23.2. When it is compared with the result of the frequency of 27.12 MHz, although the result is that the selectivity is lower, it is recognized that a characteristic of only etching of the SiN film making progress compared with the SiO₂ film and poly-Si film is the same result as that of 27.12 MHz. However, in ECR plasma using an electromagnetic wave of 2.45 GHz, even if the gas was used, etching did not produce high selectivity of the SiN film to the SiO₂ or poly film.

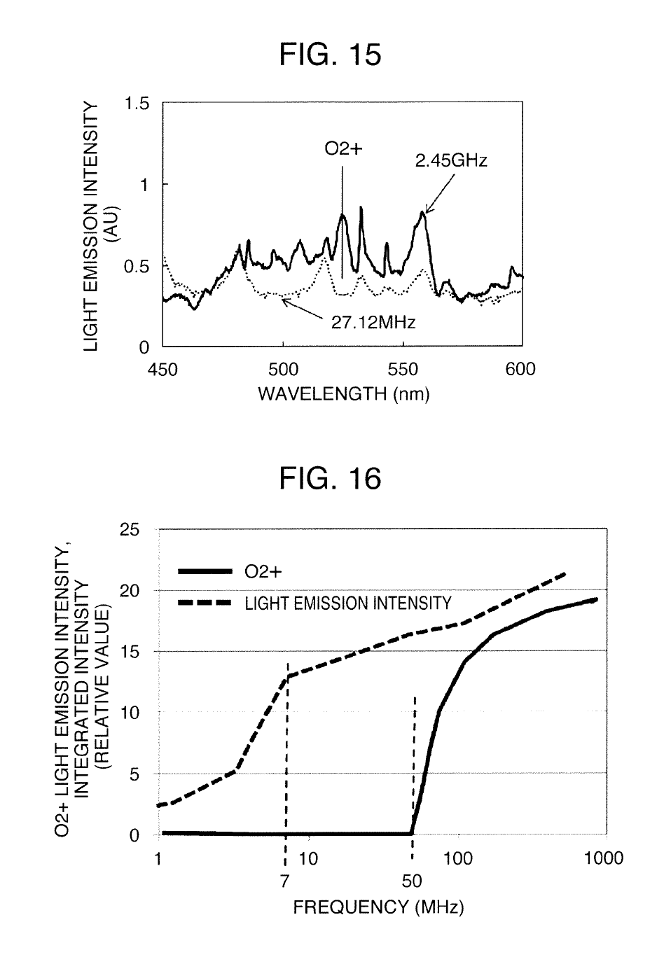

In order to make this cause clear, light emission spectral from plasma were measured. FIG. 15 shows comparison of plasma light emission intensity between an ECR plasma apparatus and the ICP plasma apparatus used in the invention by using mixed gas of O₂, CF₄ and CHF₃. As a result, it has become clear that in ECR plasma, light emission of oxygen ion of O₂⁺ is main.

Because O₂⁺ light emission requires an electron temperature of 12 eV or more, it becomes clear that in ECR plasma, ion plasma is main. On the other hand, in ICP plasma, light emission of oxygen radicals of O is main, and O₂⁺ light emission confirmed at ECR plasma is not confirmed; thus, it has become clear that plasma mainly made up of radicals whose electron temperature is low is formed.

In ECR plasma, gas decomposition is notable, intermediate radical species hardly occur, and in etching processing mainly requiring radical species, the ICP plasma apparatus has a wider region such as pressure that can be used for processing In order to obtain a region where high selective etching of the SiN film is available, light emission spectral were measured by changing a frequency of plasma excitation.

FIG. 16 shows light emission intensity of O₂⁺ and integrated light emission intensity of spectral of wavelengths from 1 nm to 900 nm. In the case of O₂⁺, light emission intensity rises from a frequency of 50 MHz and increases after that Namely, it is recognized that a plasma decomposition state changes at 50 MHz or more, and etching is not mainly executed by radicals. In addition, the integrated intensity sharply drops at a frequency of 7 MHz or less. The integrated light emission intensity represents intensity of plasma, and drop in the integrated intensity means that plasma density is attenuated and processing speed is decreased. Thus, it has become clear from this that high speed and high selective etching of the SiN film requires that the plasma excitation frequency is 7 MHz or more and 50 MHz or less.

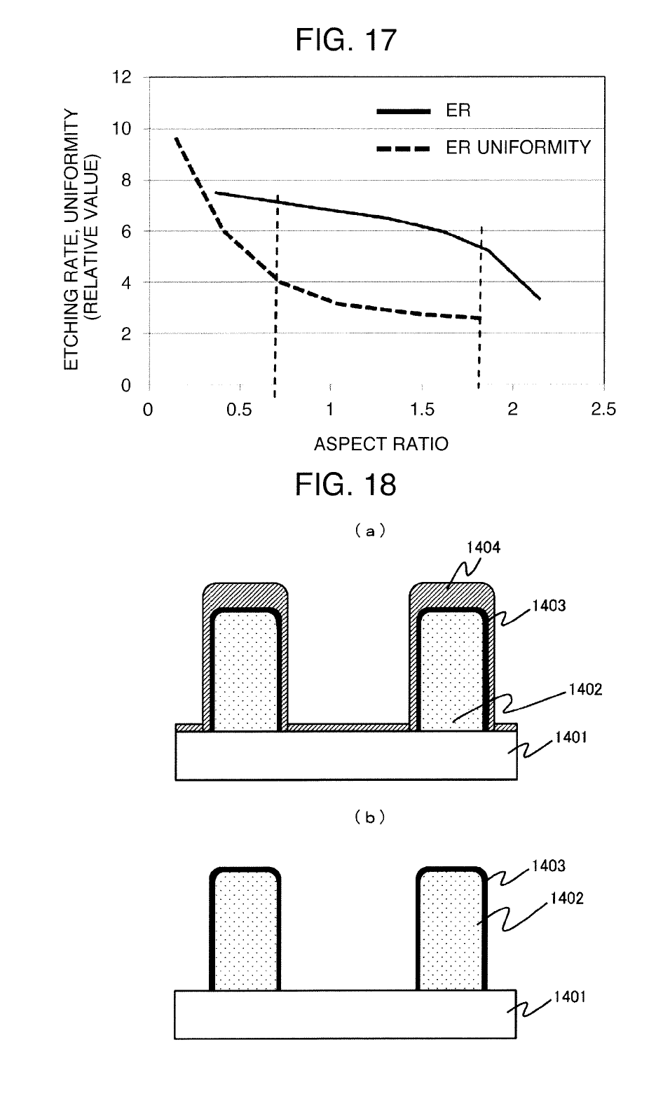

Next, an optimal value of distance L between a wafer and a gas supply port will be described. FIG. 17 shows relation of a value obtained by dividing the distance L by a wafer diameter (hereinafter called an aspect ratio) to an etching rate (denoted by ER in the figure) and its uniformity.

The etching rate decreases as the aspect ratio increases. This is because electric power per plasma unit volume decreases due to increase in the volume of the chamber. On the other hand, uniformity of the etching rate becomes worse as the aspect ratio becomes small. This is because distribution of gas flow speed becomes worse on the wafer surface when the wafer is close to the gas supply port. The optimal value of the aspect ratio is in a range from 0.7 to 1.7

Next, FIG. 18 shows a processed shape as a result of processing the wafer 109 by using the conditions shown in FIG. 14 in the example. Regarding an initial shape of the sample, poly patterns 903 of a pattern height of 150 nm with an interval of 20 nm were formed on a Si substrate 904 and on those, a thermally-oxidized film 902 was formed by 2 nm. Then, forming a SiN film 901 by 10 nm on top and by 2 nm on a side wall of the thermally-oxidized film 902, the sample was made. The sample was made so as to enable evaluation of the amount of Si recess after the SiN film 901 is etched by removing the thermally-oxidized film between the poly patterns 903.

As a result of processing for 40 s under the conditions shown in FIG. 14, a resulting shape is that the SiN film 901 of the top and side wall of the thermally-oxidized film 902 was completely removed, film thickness of the undercoating thermally-oxidized film 902 was not reduced, and surface morphology does not have convex or concave. Furthermore, it has been confirmed that there is no residual film of the SiN film 901 on the Si surface 904 between the poly patterns 903, and there is no recess on the Si surface 904.

If the selectivity of the SiN film to the SiO₂ film or poly-Si film is low, damage will be inflicted on the SiO₂ film or Si surface, but in the high selectivity etching of the present invention, that problem does not occur. In addition, in fine processing, etching amount distribution within the wafer surface is very important, but in the example, because the selectivity to the SiO₂ film and poly-Si film is sufficient, even if over-etching of more than 100% is applied, stable repeatability of the processed shape is obtained thanks to a wide process margin for damage to the undercoating SiO₂ film and for occurrence of Si recess.

Furthermore, the example enables etching with high selectivity of the SiN film to both of two different films of the undercoating SiO₂ film and poly-Si film by using one combination of gas types, and thereby it is effective to improve throughput because it reduces necessity for replacement by vacuum exhaust and rare gas introduction in order to section a processing step into multiple sub-steps, stop plasma formation and change process gas to be supplied. In addition, because control of the etching rate and selectivity can be achieved by a parameter, it is possible to adapt according to film thickness and film quality of the SiN film, and film thickness and film quality of the undercoating SiO₂ film or poly-Si film.

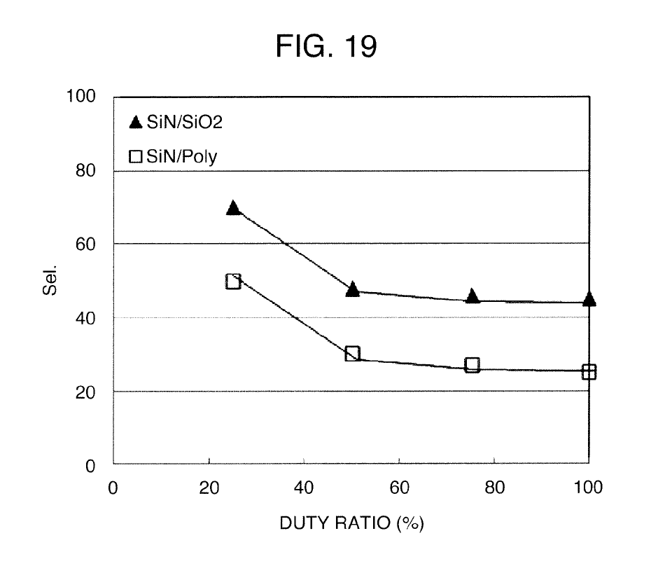

Next, explanation will be given about a case where in the example, high-frequency power from the high-frequency power supply 106 has undergone pulse modulation. FIG. 19 shows relation between a duty ratio of pulse modulation and selectivity when output of the high-frequency power supply 106 is kept constant at 27.12 MHz and a peak power of 1.5 kW.

The pulse frequency was 100 Hz. As can be seen in the figure, the selectivity increases from a point of the duty ratio being 50% or less. The apparatus has a tendency for wafer in-plane distribution of the etching rate to vary when high-frequency output power is changed, but execution of pulse modulation and changing the duty ratio enables increase in the selectivity without changing uniformity of the etching rate. The etching rate decreases due to occurrence of deposition during an off period by execution of pulse modulation, but the selectivity increases because the etching rates of SiO₂ and poly-Si come close to 0.

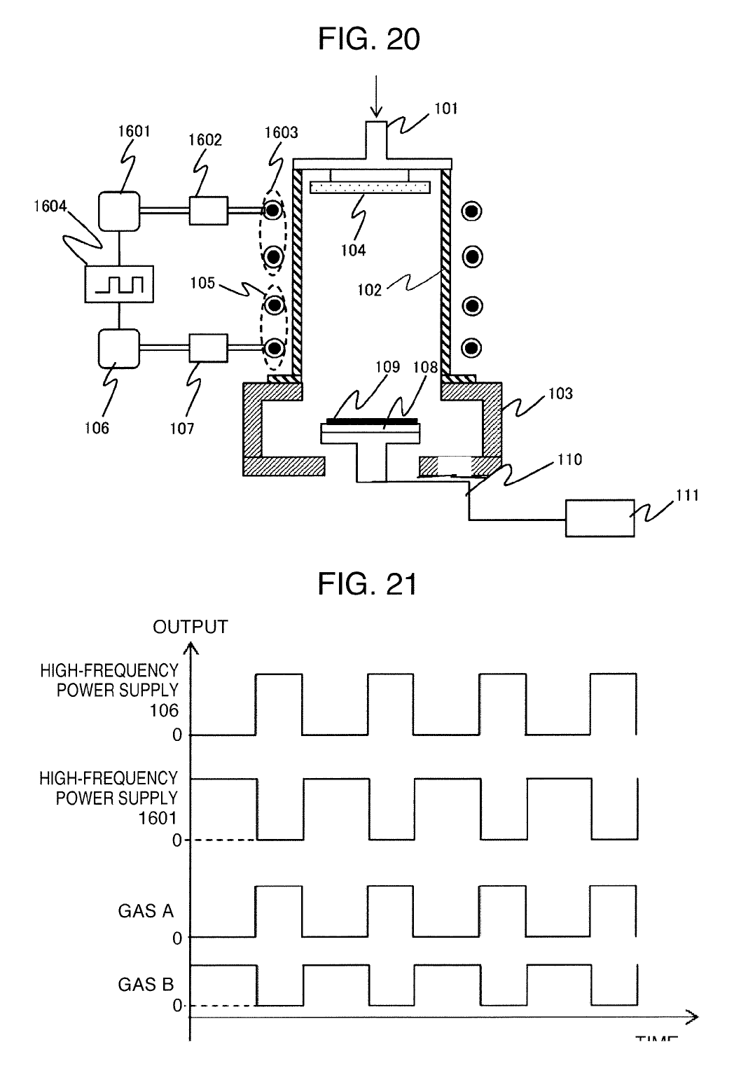

The above described example explained the plasma processing apparatus using the single induction coil 105 and the high-frequency power supply 106. Next, FIG. 20 shows an example comprising a plurality of induction coils 105 and high-frequency power supplies 106 as a variant example of the example shown in FIG. 1. The plasma processing apparatus shown in FIG. 20 comprises two induction coils: an induction coil 105 and an induction coil 1103 that is placed on the upper side of the induction coil 105 and has wound in a spiral manner around the outer circumference of the quartz chamber 102. The induction coils 105, 1103 are electrically connected with a high-frequency power supply 106 and a high-frequency power supply 1601 through auto matchers 107 and 1602, respectively, and high frequency power can be supplied independently.

When high-frequency power is supplied to the induction coil 105, plasma is formed by an induction magnetic field in the vicinity along the induction coil 105 inside the quartz chamber 102, and when high-frequency power is supplied to the induction coil 1603, plasma is formed in the same manner in the vicinity along the induction coil 1603 further away from the wafer 109. By adjusting the magnitude and frequency of high-frequency power supplied to these induction coils 105 and 1603 depending on a type of processing object film of a sample and a type of gas, a processing rate and uniformity in a surface direction of the wafer 109 can be accurately adjusted.

Furthermore, in the example in FIG. 20, by supplying output from the two high frequency power supplies 106 and 1601 to the induction coils 105 and 1603 synchronizing the output with a control signal from a pulse controller 1604, intensity of plasma formed inside the quartz chamber 102 can be temporally adjusted. This enables adjustment so that the quantity and distribution of particles which are excited, activated and supplied to the top of the wafer 109 will be as desired.

FIG. 21 is a graph showing change in output over time from the two high-frequency power supplies 106, 1601 in the variant example shown in FIG. 20. In the figure, waveforms are shown as a quadrate representing amplitude, but actually supplied power is alternating current power having that amplitude. In this example, power from the two high-frequency power supplies 106, 1601 repeats an on period when power is output at a prescribed interval or cycle and prescribed magnitude (or output at a large value) and an off period when power is 0 (or output at a smaller value). Output from the high-frequency power supplies 106, 1601 is output in synchronization, and their periods of on and off or high output and low output are reverse of each other. When one is in the on period, the other is in the off period.

Furthermore, in the example, process gas supplied into the processing chamber is switched in synchronization with output of the high-frequency power supplies 106, 1601, gas A being supplied in a period when the high-frequency power supply 106 is on, and gas B being supplied in a period when the high-frequency power supply 1601 is on. In addition, in the example, a cycle between any “on” and the next “on” of pulses is 2 seconds. Furthermore, using Ar as the gas A and O₂/CF₄/CHF₃ as the gas B enables control of adsorption of reactive gas and sputtering by Ar digitally and enables more precise processing.

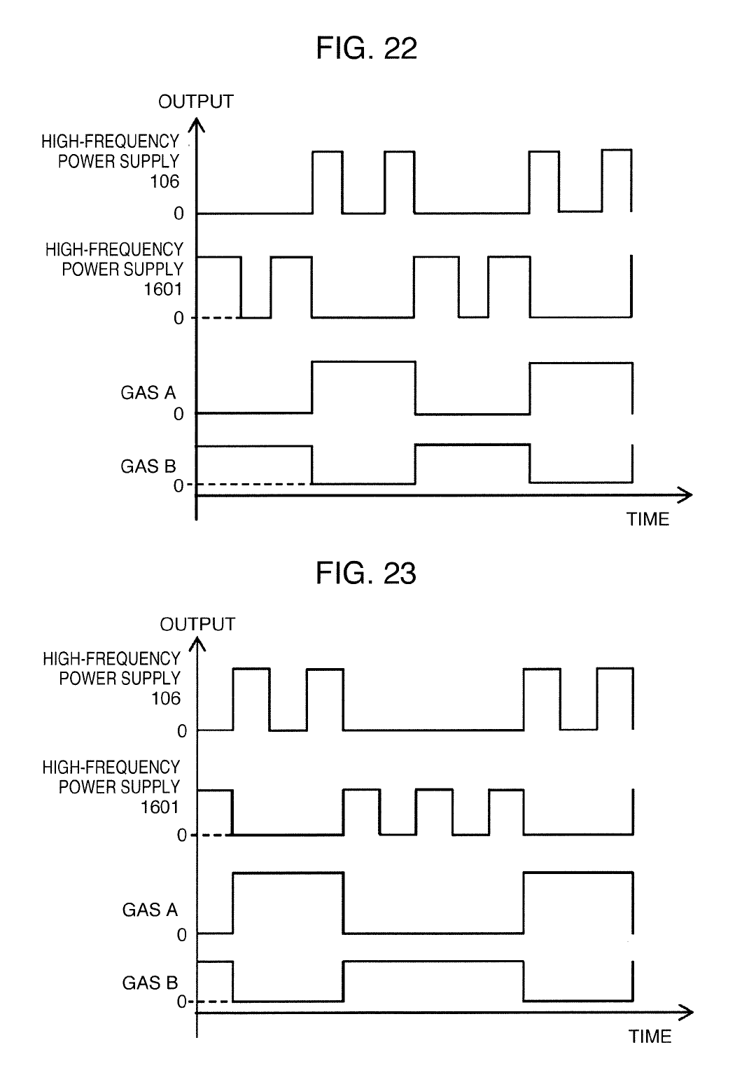

Furthermore, as shown in FIGS. 22 and 23, in response to a control command signal from the pulse controller 1604, the two high-frequency power supplies 106, 1601 repeat power output, at a prescribed cycle, in their periods of on/off or high output/low output. In each period of on or high output, output of a plurality of quadrate waves (pulses) may be repeated. The example of FIG. 22 is an example in which each of the high-frequency power supplies 106, 1601 repeats their periods of on/off or high output/low output at the same amplitude as each other, the period of on (high output) and the period of off (low output) of the former are made different in length, but the same number of pulses are repeatedly output by each of them.

On the other hand, FIG. 23 is an example in which each of the high frequency power supplies 106, 1601 repeats their periods of on/off or high output/low output at different amplitude from each other, the period of on (high output) and the period of off (low output) of the former are made different in length, and different numbers of pulses are repeatedly output by each of them. Amplitude, length of periods of on/off or high output/low output, a relative rate (duty ratio), the number of pulses and its duty ratio in each period of output from the two high-frequency power supplies 106, 1601 are more appropriately selected by a user according to conditions of processing such as material of a processing object film, pressure and time of processing, types of process gases and composition of its combination, and output values of the high-frequency power supplies 106, 1601 and operation of the pulse controllers 112, 1604 are adjusted. Such a configuration enables improvement of uniformity in the in-plane direction in processing of the wafer 109.

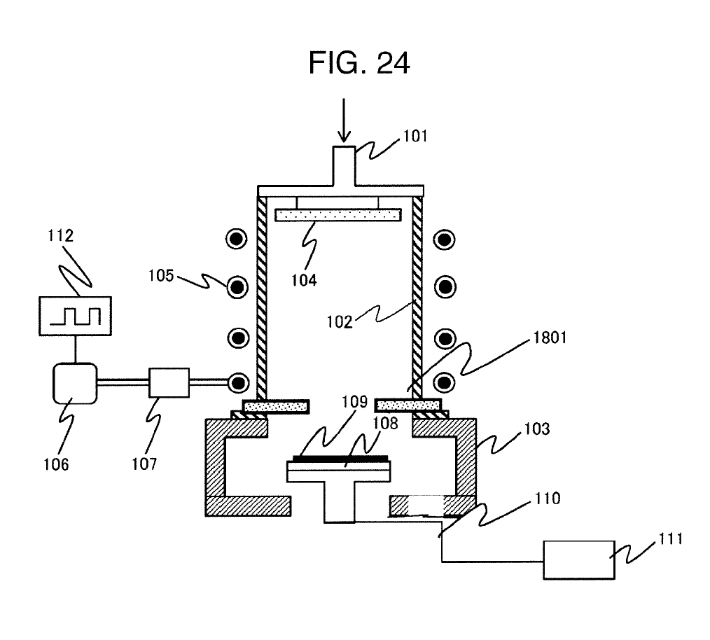

FIG. 24 shows a configuration to adjust uniformity of an etching rate to a desired value by a member placed inside the aluminum chamber 103 in the plasma processing apparatus of the example shown in FIG. 1. In the example, there is equipped a ring member 1801 composed of SiN having a cylindrical shape and placed inside between the lower end of the quartz chamber 102 and the upper end of the aluminum chamber 103 that is placed under and connected with the quartz chamber 102.

In etching, there occurs a phenomenon in which byproducts detached from a wafer decompose in plasma, and attach again to the wafer, and the reattachment reduces the etching rate. Generally, the central part of the wafer 109 away from the exhaust port in the processing chamber tends to be lower in the etching rate due to abundance of reattachment of byproducts compared with the outer circumference part of the wafer 109.

In order to improve this, the apparatus in FIG. 24 places the ring member 1801 composed of material including SiN which is the same quality of material as material to be etched, which is SiN in the example, inside the lower end of the quartz chamber 102 and inside the upper end of the aluminum chamber 103, generates byproducts from those places, and uniforms density distribution of the byproducts in the processing chamber at the central part and outer circumference part of the wafer 109; thereby enabling improvement of wafer in-plane distribution of the etching rate.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing method for performing etch-back of a SiN film as a processing object of a film structure including a SiO₂ film and the SiN film or a Si film and the SiN film on a surface of a substrate placed in a processing chamber by using inductively coupled plasma formed in the processing chamber by supplying process gas including CHF₃ or CF₄ and O₂ gas into the processing chamber inside a vacuum vessel and supplying RF power of 7-50 MHz to an induction coil surrounding an outer circumference of the processing chamber.

2. The inductively coupled plasma processing method according to claim 1, using processing pressure in a pressure range of 50 Pa or more.

3. The plasma processing method according to claim 1,
performing high selectivity etching of the SiN film by making oxygen concentration ratio into a region of high concentration of at least 80% or more than fluoromethane-based gas and fluorocarbon-based gas in a gas flow rate ratio of oxygen, the fluoromethane-based gas and the fluorocarbon-based gas.

4. The plasma processing method according to claim 2,
performing high selectivity etching of the SiN film by making oxygen concentration ratio into a region of high concentration of at least 80% or more than fluoromethane-based gas and fluorocarbon-based gas in a gas flow rate ratio of oxygen, the fluoromethane-based gas and the fluorocarbon-based gas.

5. The plasma processing method according to claim 1,
wherein a frequency of a high-frequency power supply supplied to the induction coil is a frequency of 7 MHz-50 MHz.

6. The plasma processing method according to claim 2,
wherein a frequency of a high-frequency power supply supplied to the induction coil is a frequency of 7 MHz-50 MHz.

7. The plasma processing method according to claim 3,
wherein a frequency of a high-frequency power supply supplied to the induction coil is a frequency of 7 MHz-50 MHz.

8. The plasma processing method according to claim 4,
wherein a frequency of a high-frequency power supply supplied to the induction coil is a frequency of 7 MHz-50 MHz.

9. The plasma processing method according to claim 1,
wherein output of the high-frequency power supply has undergone pulse modulation with a duty ratio of 50% or less.

10. The plasma processing method according to claim 2,
wherein output of the high-frequency power supply has undergone pulse modulation with a duty ratio of 50% or less.

11. The plasma processing method according to claim 3,
wherein output of the high-frequency power supply has undergone pulse modulation with a duty ratio of 50% or less.

12. The plasma processing method according to claim 4,
wherein output of the high-frequency power supply has undergone pulse modulation with a duty ratio of 50% or less.
